(19) United States
(12) Patent Application Publication
(10) Pub. No.: US 2024/0292584 A1
(43) Pub. Date: Aug. 29, 2024

(54) DISPLAY DEVICE

(71) Applicant: LG DISPLAY CO., LTD, Seoul (KR)

(72) Inventor: Sungwoo Myung, Gyeongsangnam-do (KR)

(21) Appl. No.: 18/414,139

(22) Filed: Jan. 16, 2024

(30) Foreign Application Priority Data
Feb. 28, 2023 (KR) 10-2023-0027210

(51) Int. Cl. H05K 9/00; H05K 7/20

(52) U.S. Cl. CPC H05K 9/0084; H05K 7/20963; H05K 9/0015

(57) ABSTRACT

Embodiments of the disclosure relate to a display device and, more specifically, may provide a display device capable of removing EMI formed in an electrical floating area by comprising a substrate including a display area and a non-display area, a pad area disposed in the non-display area, a printed circuit board electrically connected to the pad area, an encapsulation layer formed of a metal material and disposed on the substrate, a protection layer formed of a non-metallic material and disposed on the encapsulation layer, a heat dissipation plate disposed on the protection layer, and a ground member positioned on the substrate and connected between the pad area and the encapsulation layer.

### CROSS-REFERENCE TO RELATED APPLICATION

This application claims priority from Korean Patent Application No. 10-2023-0027210, filed on Feb. 28, 2023, which is hereby incorporated by reference for all purposes as if fully set forth herein.

### BACKGROUND

### Field

Embodiments of the disclosure relate to a display device that may eliminate electro-magnetic interference (EMI) by electrically connecting an electrical floating area through a ground member.

### Description of Related Art

With the recent growth of intelligence society and the development of various portable electronic devices, e.g., mobile communication terminals and laptop computers, display devices, as visual information transfer media, are of more significance.

Displays may be divided into an emissive type, such as cathode ray tube (CRT), light luminescence (EL), light emitting diode (LED), vacuum fluorescent display (VFD), field emission display (FED), plasma display panel (PDP), and organic light emitting diode (OLED), and a non-emissive type, such as liquid crystal display (LCD), which is not self-emissive.

The display device may include thin film transistors (TFTs), a substrate having a display surface for displaying images, an encapsulation layer, a heat dissipation plate, a printed circuit board, etc. which may be electrically connected to each other via conductive tape. Accordingly, each member may emit EMI through the ground portion of the printed circuit board.

However, when a non-conductive layer is added between the substrate and the printed circuit board, an electrical floating area occurs. If a floating area occurs, removal of EMI fails, causing distortion of the signal supplied to the substrate, with the result of image quality degradation.

### BRIEF SUMMARY

Accordingly, the inventors of the disclosure have invented a display device capable of eliminating EMI by electrically connecting a layer of non-conductive material positioned between a substrate and a printed circuit board through a ground member.

Embodiments of the disclosure may provide a display device capable of efficiently securing an installation space for each component by electrically connecting a layer of non-conductive material positioned between a substrate and a printed circuit board through a ground member to thereby eliminate the need for conductive tape.

Embodiments of the disclosure may provide a high-definition display device capable of removing EMI formed in an electrical floating area by providing the EMI to the printed circuit board.

Embodiments of the disclosure may provide a display device comprising a substrate including a display area and a non-display area, a pad area disposed in the non-display area, a printed circuit board electrically connected to the pad area, an encapsulation layer formed of a metal material and disposed on the substrate, a protection layer formed of a non-metallic material and disposed on the encapsulation layer, a heat dissipation plate disposed on the protection layer, and a ground member positioned on the substrate and connected between the pad area and the encapsulation layer.

According to embodiments of the disclosure, there may be provided a display device capable of implementing a simplified and unified product by forming a ground member on a substrate through deposition of a single metal material.

### DESCRIPTION OF DRAWINGS

The above and other objects, features, and advantages of the disclosure will be more clearly understood from the following detailed description, taken in conjunction with the accompanying drawings, in which:

FIG. 1 is a plan view illustrating a display device according to an embodiment of the disclosure;

FIG. 2 is a cross-sectional view taken along line A-A′ of FIG. 1;

FIG. 3 is a rear perspective view illustrating a display device according to embodiments of the disclosure; and

FIG. 4 is an exploded perspective view illustrating a display device according to an embodiment of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

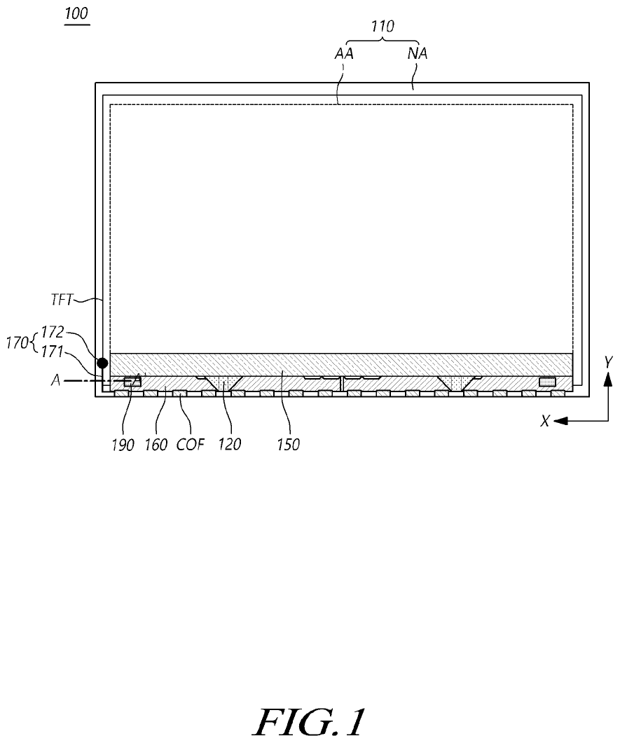

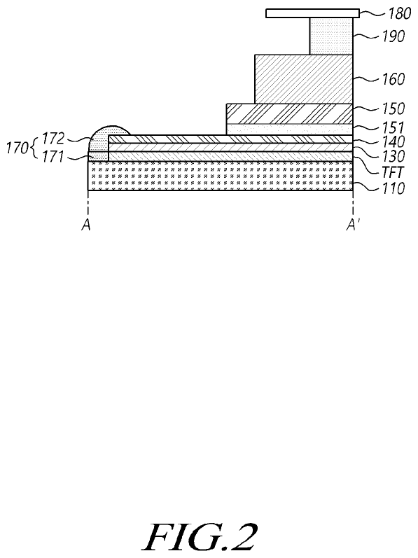

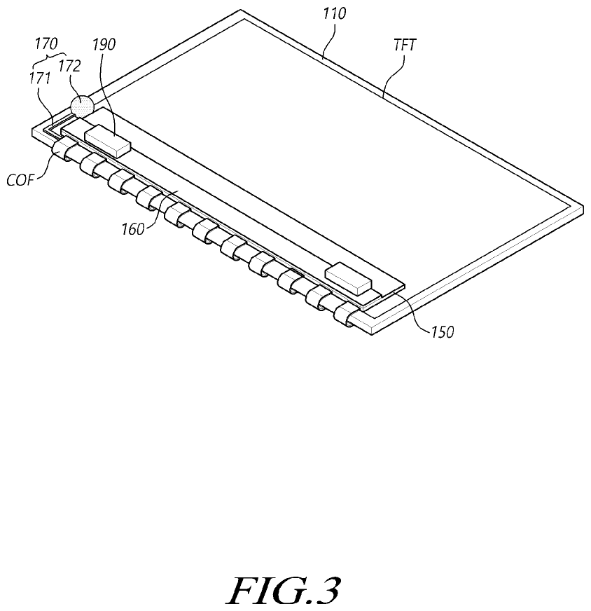

FIG. 1 is a plan view illustrating a display device according to an embodiment of the disclosure. FIG. 2 is a cross-sectional view taken along line A-A′ of FIG. 1. FIG. 3 is a rear perspective view illustrating a display device according to embodiments of the disclosure.

For convenience of description, it is assumed hereinafter that the display surface for implementing an image on the substrate faces forward.

Referring to FIGS. 1 to 3, a display device 100 may include a substrate 110, a pad area 120, an encapsulation layer 130, a protection layer 140, a heat dissipation plate 150, a printed circuit board 160, and a ground member 170.

The substrate 110 is a panel on which an image is implemented, and may be formed of one selected from among a liquid crystal display (LCD) device, a field emission display (FED) device, an electroluminescence display (ELD) device, and an organic light emitting diode (OLED).

A pixel array for implementing an image, a circuit for driving the pixel array, lines, and components may be disposed on the substrate 110. For example, the substrate 110 may be formed of a glass material, and may include a display area AA in which an image is displayed and a non-display area NA in which no image is displayed.

The non-display area NA may be formed outside the substrate 110 and may include a plurality of thin film transistors TFT. For example, the transistors TFT may be a driving circuit transistor included in a gate driving circuit of a gate in panel (GIP) type disposed in the non-display area NA or various types of dummy transistors disposed in the non-display area NA. As another example, when the pad to be described below is a ground-only pad, the transistor TFT may be a ground-only transistor.

Meanwhile, although not shown, a plurality of transistors for supplying signals to pixels may also be provided in the display area AA.

The pad area 120 may be disposed at one side edge of the substrate 110 and may be electrically connected to the transistor TFT. Here, the pad area 120 refers to an area in which a pad formed of a conductive material is provided and electrically connectable. For example, the pad of the pad area 120 may be formed of a conductive material such as metal or the like, and at least one pad may be provided to be electrically connected to the transistors TFT disposed in the non-display area NA. Further, the whole or part of the pad area 120 may be exposed to the outside without being covered by other members.

An encapsulation layer 130 may cover a portion of the substrate 110 on the substrate 110. For example, the encapsulation layer 130 may cover from the display area AA of the substrate 110 to the transistor TFT of the non-display area NA, and may be formed of a metal material. As described above, when the encapsulation layer 130 is formed of a metal material, the encapsulation layer 130 may act as a reflector to allow light from the substrate 110 to be emitted toward the display, thereby enhancing light efficiency.

The protection layer 140 protects members positioned between the substrate 110 and the protection layer 140, and may be formed of a non-metallic material. For example, the protection layer 140 may be formed of a polymer material such as polyethylene terephthalate (PET), cycloolefin polymer (COP), acrylic, or the like.

Meanwhile, as the protection layer 140 is formed of a non-metallic material, the encapsulation layer 130 may not be electrically connected to the printed circuit board 160 to be described below, and thus may be in an electrically floating state. When such electrical floating occurs, external electromagnetic interference (EMI) may remain in the encapsulation layer 130, causing distortion of the signal supplied to the substrate 110 with the result of image quality degradation. To address such issues, a ground member 170 may be provided to electrically connect the encapsulation layer 130 and the printed circuit board 160, which is described below.

The heat dissipation plate 150 may be disposed on the protection layer 140, and may discharge the heat generated from the substrate 110, the printed circuit board 160, and the like to the outside. For example, the heat dissipation plate 150 may be elongated in the X-axis direction in the drawings, and may be disposed below the protection layer 140.

The heat dissipation plate 150 may be formed of a metal material having high heat dissipation efficiency, such as aluminum (Al), copper (Cu), or the like, and may be attached to the protection layer 140 through an adhesive 151. Here, the adhesive 151 may be a pressure-sensitive adhesive PSA having a stable adhesive property and good heat resistance.

The printed circuit board 160 may be disposed on the heat dissipation plate 150 and may be electrically connected to the pad area 120. For example, the printed circuit board 160 may be disposed on the heat dissipation plate 150, and may generate a source signal for driving the substrate 110 and a plurality of timing signals for applying the source signals at an appropriate time.

The printed circuit board 160 may be electrically connected to the pad area 120 through a chip on film (COF) having flexibility. As the printed circuit board 160 is so connected to the pad area 120 through the COF, a control signal may be transmitted to the transistor TFT electrically connected to the pad area 120.

For example, a plurality of COFs may be provided to be spaced apart from each other in the X-axis direction, and one side may be connected to the substrate 110 while the other side may be connected to the printed circuit board 160. The COF may be bent to the rear surface of the substrate 110. Accordingly, the printed circuit board 160 connected to the COF may be positioned opposite to the surface where the image of the substrate 110 is displayed, i.e., on the rear surface of the substrate 110, to be disposed on the heat dissipation plate 150.

The ground member 170 may electrically connect the encapsulation layer 130 and the printed circuit board 160. As the encapsulation layer 130 and the printed circuit board 160 are so electrically connected through the ground member 170, an electrical floating phenomenon occurring between the encapsulation layer 130 formed of a conductive material and the protection layer 140 formed of a non-conductive material may be prevented. In other words, since the printed circuit board 160 is electrically connected to the heat dissipation plate 150, the COF, the pad area 120, and the transistor TFT, the printed circuit board 160 may emit EMI through the ground portion, but the encapsulation layer 130 is not electrically connected with the printed circuit board 160 due to the protection layer 140 disposed between the encapsulation layer 130 and the heat dissipation plate 150. In this case, since the encapsulation layer 130 and the heat dissipation plate 150 are electrically floating therebetween, EMI may remain on the encapsulation layer 130 without being removed, distorting the signal supplied to the substrate 110.

In order to remove the EMI, the encapsulation layer 130 and the printed circuit board 160 are electrically connected through the ground member 170. For example, the ground member 170 may be connected to the encapsulation layer 130 and the ground portion of the printed circuit board 160, and EMI remaining on the encapsulation layer 130 may be removed through the ground portion of the printed circuit board 160.

The ground member 170 may include a ground pattern 171 and a conductive member 172.

The ground pattern 171 may be patterned on the substrate 110 to have a preset shape and may electrically connect the transistor TFT and the pad area 120.

The transistor TFT connected to the ground pattern 171 may be at least one of driving circuit transistors in the gate driving circuit disposed in the non-display area NA and a dummy transistor disposed in the non-display area NA.

The driving circuit transistor and the dummy transistor may include a semiconductor layer and a source/drain electrode connected to the semiconductor layer and a gate electrode. The source/drain electrode and the gate electrode may be a single layer or a multi-layer structure formed of any one of, or an alloy of, molybdenum (Mo), aluminum (Al), chromium (Cr), gold (Au), titanium (Ti), nickel (Ni), neodymium (Nd), and copper (Cu).

For example, the ground pattern 171 may extend to the pad area 120 along the edge of the substrate 110, and may be formed of the same material and on the same layer as one of the metal layers forming the transistor TFT. Specifically, the ground pattern 171 may be positioned at the same height as one of the metal layers forming the transistor TFT on the substrate 110, and may electrically connect the transistor TFT and the pad area 120 by partially contacting the transistor TFT and the pad area 120.

The ground pattern 171 may be formed by depositing a metal material on the substrate 110. For example, a metal material may be deposited on the substrate 110 in a predetermined pattern through a sputtering method, but the deposition method is not limited thereto.

Further, the ground pattern 171 may be formed by attaching a conductive tape to the substrate 110. For example, the conductive tape may include a conductive material such as aluminum (Al), silver (Ag), or the like, and may be attached to the substrate 110.

The conductive member 172 may be formed to surround a portion of the ground pattern 171, the encapsulation layer 130, and the protection layer 140. For example, the conductive member 172 may be formed of silver (Ag) having good conductivity, and may have a spherical surface.

Referring to FIG. 2, the conductive member 172 may be formed to cover a side rear surface of the ground pattern 171, side portions of the encapsulation layer 130 and the protection layer 140, and a portion of the rear surface of the protection layer 140. As described above, since the encapsulation layer 130 and the printed circuit board 160 may be electrically connected through the conductive member 172 and the ground pattern 171, EMI remaining on the encapsulation layer 130 may be removed through the ground portion of the printed circuit board 160. For example, the EMI formed on the encapsulation layer 130 may be removed along the path of conductive member 172→ground pattern 171→transistor TFT in non-display area NA→pad area 120→COF→printed circuit board 160.

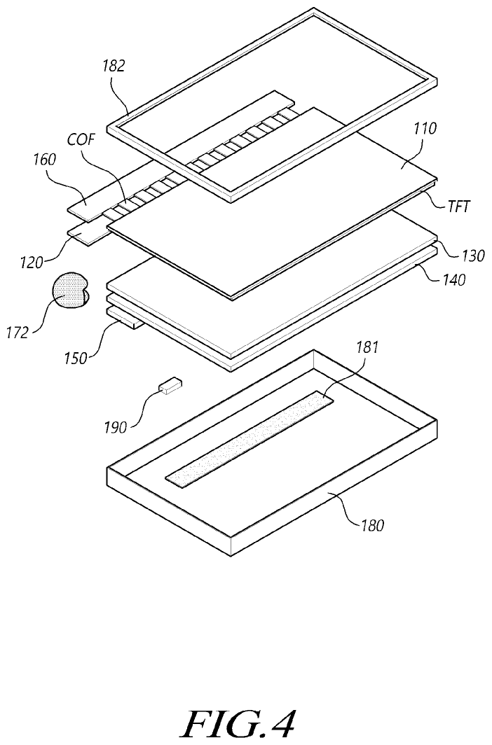

FIG. 4 is an exploded perspective view illustrating a display device according to an embodiment of the disclosure. In this embodiment, the description focuses primarily on differences from the above-described embodiment.

Referring to FIG. 4, the display device 100 may further include a back cover 180 and a conductive gasket 190.

The back cover 180 may cover the rear surface of the substrate 110, and may have a receiving space to receive components such as the substrate 110. The back cover 180 may be coupled to the rear surface of the side frame 182 that surrounds and supports the side portion of the substrate 110.

The back cover 180 of the present embodiment may act as a ground to remove EMI. For example, the back cover 180 may remove EMI by electrically connecting the ground potential 181 formed therein to the printed circuit board 160 through the conductive gasket 190.

The conductive gasket 190 may electrically connect the back cover 180 and the printed circuit board 160, and may be disposed between the back cover 180 and the printed circuit board 160. For example, the conductive gasket 190 may include a conductive material such as aluminum (Al), silver (Ag), or the like, and may be formed of an elastic material.

As such, when the conductive gasket 190 is formed of an elastic material, the conductive gasket 190 may be compressed and deformed when the printed circuit board 160 and the back cover 180 are coupled to the side frame 182. Accordingly, the conductive gasket 190 may correspond to a thickness change of each member, and may prevent the back cover 180 and the printed circuit board 160 from being short-circuited due to a phenomenon in which the back cover 180 and the printed circuit board 160 are lifted.

One side of the conductive gasket 190 may be connected to the printed circuit board 160, and the other side of the conductive gasket 190 may be electrically connected to the ground potential 181 of the back cover 180. In this case, the EMI formed on the encapsulation layer 130 may be removed along the path of conductive member 172→ground pattern 171→transistor TFT in non-display area NA-pad area 120→COF→printed circuit board 160→conductive gasket 190→back cover 180.

As described above, the display device 100 according to embodiments of the disclosure may remove EMI by electrically connecting an electrical floating area through the ground member 170, allowing for a high-definition display device.

Embodiments of the disclosure described above are briefly described below.

According to embodiments of the disclosure, there may be provided a display device comprising a substrate including a display area and a non-display area, a pad area disposed in the non-display area, a printed circuit board electrically connected to the pad area, an encapsulation layer formed of a metal material and disposed on the substrate, a protection layer formed of a non-metallic material and disposed on the encapsulation layer, a heat dissipation plate disposed on the protection layer, and a ground member positioned on the substrate and connected between the pad area and the encapsulation layer.

According to embodiments of the disclosure, the display device may further comprise a transistor electrically connected to a pad disposed in the pad area, and being disposed in the non-display area.

According to embodiments of the disclosure, the transistor may include a driving circuit transistor included in a gate driving circuit disposed in the non-display area or a dummy transistor disposed in the non-display area.

The ground member may include a ground pattern patterned on the substrate to have a preset shape to electrically connect the transistor and the pad area and a conductive member formed to surround a portion of the protection layer, the encapsulation layer, and the ground pattern.

According to embodiments of the disclosure, the ground pattern may be formed on the same layer as at least one metal layer of the transistor.

According to embodiments of the disclosure, the ground pattern may extend to the pad area along an edge of the substrate.

According to embodiments of the disclosure, the ground pattern may be formed by depositing a metal material on the substrate.

According to embodiments of the disclosure, the ground pattern may be formed by attaching a conductive tape to the substrate.

According to embodiments of the disclosure, the conductive member may be formed to cover a side rear surface of the ground pattern, a side portion of the encapsulation layer and the protection layer, and a rear surface of the protection layer.

According to embodiments of the disclosure, the conductive member may be formed of silver (Ag) and has a spherical surface.

According to embodiments of the disclosure, the heat dissipation plate may be attached to the protection layer through an adhesive.

According to embodiments of the disclosure, the display device may further comprise a chip on film (COF) electrically connecting the pad area and the printed circuit board.

According to embodiments of the disclosure, the display device may further comprise a back cover covering a rear surface of the substrate and a conductive gasket disposed between the back cover and the printed circuit board.

According to an embodiment, the back cover may include a ground potential, and the conductive gasket may be electrically connected to the ground potential of the back cover and the printed circuit board.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate including a display area and a non-display area;
a pad area disposed in the non-display area;
a printed circuit board electrically connected to the pad area;
an encapsulation layer formed of a metal material and disposed on the substrate;
a protection layer formed of a non-metallic material and disposed on the encapsulation layer;
a heat dissipation plate disposed on the protection layer; and
a ground member positioned on the substrate and connected between the pad area and the encapsulation layer.

2. The display device of claim 1, further comprising a transistor electrically connected to a pad disposed in the pad area, and disposed in the non-display area.

3. The display device of claim 2, wherein the transistor includes a driving circuit transistor included in a gate driving circuit disposed in the non-display area or a dummy transistor disposed in the non-display area.

4. The display device of claim 2, wherein the ground member includes:
a ground pattern patterned on the substrate to have a preset shape and electrically connect the transistor to the pad area; and
a conductive member surrounding a portion of the protection layer, the encapsulation layer, and the ground pattern.

5. The display device of claim 4, wherein the ground pattern is formed on a same layer as at least one metal layer of the transistor.

6. The display device of claim 4, wherein the ground pattern extends to the pad area along an edge of the substrate.

7. The display device of claim 4, wherein the ground pattern is formed by depositing another metal material on the substrate.

8. The display device of claim 4, wherein the ground pattern is formed by attaching a conductive tape to the substrate.

9. The display device of claim 4, wherein the conductive member is formed to cover a side rear surface of the ground pattern, a side portion of the encapsulation layer and the protection layer, and a rear surface of the protection layer.

10. The display device of claim 4, wherein the conductive member is formed of silver (Ag) and has a spherical surface.

11. The display device of claim 1, wherein the heat dissipation plate is attached to the protection layer through an adhesive.

12. The display device of claim 1, further comprising a chip-on-film electrically connecting the pad area to the printed circuit board.

13. The display device of claim 1, further comprising:
a back cover covering a rear surface of the substrate; and
a conductive gasket disposed between the back cover and the printed circuit board.

14. The display device of claim 13, wherein the back cover includes a ground potential, and wherein the conductive gasket is electrically connected to the ground potential of the back cover and the printed circuit board.
